(19) United States
(12) Patent Application Publication
(10) Pub. No.: US 2009/0292962 A1
(43) Pub. Date: Nov. 26, 2009

(54) Integrated circuit with inter-symbol interference self-testing

(75) Inventors: Jason Thurston, Raleigh, NC (US); Carl Thomas Gray, Apex, NC (US)

Correspondence Address: NIXON & VANDERHYE P.C., 901 N. Glebe Road, 11th Floor, Arlington, VA, 22203-1808, US

(73) Assignee: ARM Limited, Cambridge (GB)

(21) Appl. No.: 12/153,794

(22) Filed: May 23, 2008

(51) Int. Cl. G01R 31/3183; G06F 11/263

(52) U.S. Cl. 714/716; 714/E11.177

(57) ABSTRACT

An integrated circuit 2 having a data receiver circuit 14 for a serial data signal also includes a test data generating circuit 24 for self-test purposes. The test generating circuit includes a filter circuit 230, 32, 34, 36 which processes an input test serial data signal to generate an output test serial data signal having enhanced inter-symbol interference for loopback to the data receiver circuit so as to test that data receiver circuit.

### BACKGROUND OF THE INVENTION

1. Field of the Invention

This invention relates to the field of integrated circuits. More particularly, this invention relates to the field of integrated circuits having data receiver circuits for receiving a serial data signal which is subject to inter-symbol interference.

2. Description of the Prior Art

It is known to provide integrated circuits with data receiver circuits for receiving a serial data signal. As the data rate of the serial data signals has increased, the problems associated with inter-symbol interference (ISI) have also increased. Inter-symbol interference is an effect within a serial data stream whereby the data value of a bit produces an unwanted change in the signal value associated with the transmission of neighbouring bits. In order to help address this issue it is known to provide data transmitter circuits with emphasis filters seeking to reduce the amount of inter-symbol interference within an output serial data signal to be transmitted.

It is also desired to be able to test that an integrated circuit including a data receiver circuit is able to cope with an anticipated amount of inter-symbol interference within a serial data stream it is to receive. Such testing may be part of manufacturing tests to confirm that an individual integrated circuit which has been manufactured has been manufactured correctly. A test may also be performed to debug a design of an integrated circuit to ensure that data communication functions correctly in anticipated operational conditions and/or as part of design characterisation to determine what are the limits in the operation of a data receiver circuit which has been designed (e.g. to check that these meet the design criteria). In order to achieve these test requirements known techniques utilise specialised external test apparatus for generating a test serial data signal to be applied to an integrated circuit including a data receiver circuit. This external test equipment is expensive, comparatively slow to use, highly specialised in nature and can be specific to individual designs. Testing data receiver circuits of integrated circuits in this way accordingly represents an increasing practical difficulty.

### SUMMARY OF THE INVENTION

Viewed from one aspect the present invention provides an integrated circuit comprising:

a data receiver circuit; and

a test data generating circuit; wherein

said test data generating circuit includes a filter circuit responsive to an input test serial data signal to generate an output test serial data signal having enhanced inter-symbol interference for testing said data receiver circuit.

The present technique recognises that the integrated circuit itself may include its own test data generating circuit having a filter circuit for deliberately enhancing inter-symbol interference within a serial data signal so as to form an output test data signal which can be used to test the data receiver circuit of the integrated circuit. The provision of such a test data generating circuit within the integrated circuit itself for the purposes of self-test by deliberately enhancing inter-symbol interference within a serial data signal moves against the normal prejudice which is to provide on-chip circuits which reduce inter-symbol interference. Furthermore, in practice the overhead associated with the provision of the test data generating circuit more than justifies its inclusion given the savings achieved by avoiding the requirements for the external test equipment discussed above.

In some embodiments the filter circuit can operate in a plurality of modes including both a test mode in which it enhances inter-symbol interference and a non-test mode in which it reduces inter-symbol interference. In practice a filter circuit which is often already included within an integrated circuit for the operational purpose of reducing inter-symbol interference can be readily reused by a minor reconfiguration to enhance inter-symbol interference for the purposes of generating a test serial data signal. This reduces the overhead associated with the provision of the test data generating circuit.

In some embodiments the non-test mode discussed above may be the normal operational mode and the test data generating circuit may be a data transmitter circuit which includes a filter circuit that is normally used to reduce inter-symbol interference and yet can be reconfigured to enhance inter-symbol interference for the purposes of test.

The self-test capability can use a loopback connection to carry the output test serial data signal from the test signal generating circuit back to the data receiver circuit. This loopback connection may be an internal path within the integrated circuit (selectively switched) or may be an external path between an output and an input of the integrated circuit (e.g. pins or pads).

The filter circuit used to enhance the inter-symbol interference can have a variety of different forms. One possible form is a finite impulse response filter having a plurality of filter stages.

The reconfiguration of a filter circuit in the form of a finite impulse response circuit between a test mode and a non-test mode may be advantageously achieved by changing one or more associated coefficient values when the filter circuit changes between the test mode and the non-test mode.

The changing of the associated filter coefficients of such a finite impulse response filter may be performed such that during the test mode the outputs from different filter stages are constructively combined to enhance inter-symbol interference whereas in the non-test mode the outputs from filter stages are destructively combined to reduce inter-symbol interference.

One form of finite impulse response filter that provides a good balance between complexity and performance in at least the operational mode is a three stage filter.

The output test serial data signal can be used to test the data receiver circuit in a variety of different ways including stress testing the data receiver circuit. The tests performed may be manufacturing tests seeking to determine whether an individual integrated circuit has been correctly manufactured, design characterisation tests seeking to determine whether a given design is correct and/or debug testing seeking to determine whether a given design functions to receive expected stressed data.

While the data receiver circuit could have a variety of different forms, the above techniques are well suited to the testing of a data receiver circuit that is formed to receive a stream of self-timed serial data.

Viewed from another aspect the present invention provided an integrated circuit comprising:

data receiver means for receiving data; and

test data generating means for generating test data; wherein

said test data generating means includes filter means responsive to an input test serial data signal to generate an output test serial data signal having enhanced inter-symbol interference for testing said data receiver means.

Viewed from a further aspect the present invention provides a method of self-testing an integrated circuit having a data receiver circuit, said method comprising the steps of:

generating from an input test serial data signal using a filter circuit within said integrated circuit an output test serial data signal having enhanced inter-symbol interference; and

supplying said output test serial data signal to said data receiver circuit.

The above, and other objects, features and advantages of this invention will be apparent from the following detailed description of illustrative embodiments which is to be read in connection with the accompanying drawings.

### BRIEF DESCRIPTION OF THE DRAWINGS

FIG. 1 schematically illustrates an integrated circuit including a data receiver circuit, a data transmitter circuit and various other circuit components;

FIG. 2 schematically illustrates a data receiver circuit and a data transmitter circuit for use in self-testing;

FIGS. 3A, 3B, 3C and 3D schematically illustrate the operation of a two-stage finite impulse response filter during an operational mode so as to reduce inter-symbol interference;

FIGS. 4A, 4B and 4C schematically illustrate the reuse of the filter of FIGS. 3A, 3B, 3C and 3D configured to enhance inter-symbol interference; and

FIGS. 5A, 5B, 5C and 5D schematically illustrate a three-stage finite impulse response filter being used in an operational mode to reduce inter-symbol interference and in a test mode to enhance inter-symbol interference.

### DESCRIPTION OF THE PREFERRED EMBODIMENTS

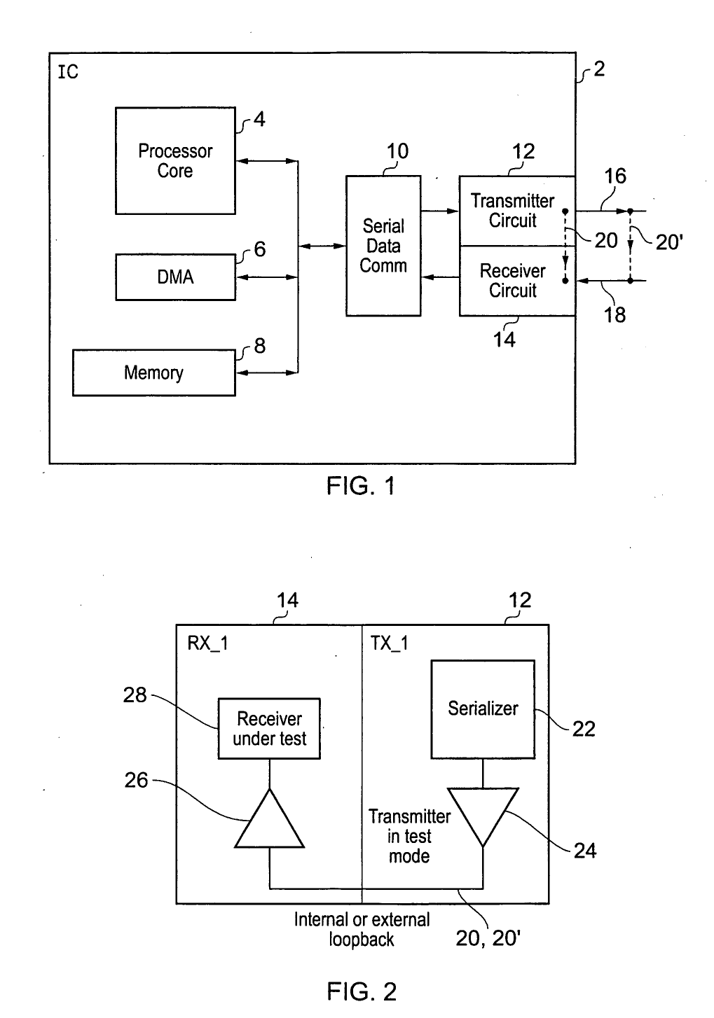

FIG. 1 schematically illustrates an integrated circuit 2 including a processor core 4, a DMA unit 6, a memory 8, a serial data communication circuit 10, a data transmitter circuit 12 and a data receiver circuit 14. It will be appreciated that such an integrated circuit 2 will typically include many more circuit blocks and/or different circuit blocks. The data transmitter circuit 12 receives an input serial data signal from the serial data communication circuit 10 and generates an output serial data signal 16. The data receiver circuit 14 receives a serial data signal 18 from outside the integrated circuit 2 and generates a serial data stream which is supplied to the serial data communication circuit 10. The serial data signal can be a self-timed serial data signal, such as, for example, a high data rate serial data signal used in PCI Express.

FIG. 1 also illustrates two possible loopback connections 20, 20′ which may be used to direct the serial data signal generated by the data transmitter circuit 12 to the data receiver circuit 14 for the purposes of self-test. The loopback connection can be an internal loopback 20 or an external loopback 20′. The self-testing performed may be part of manufacturing test conducted upon individual integrated circuits to ensure they have been correctly manufactured (e.g. binning between functioning and non-functioning circuits or between circuits having different performance specifications). The test performed could alternatively or additionally be part of design characterisation to test that the data receiver circuit for a given design of integrated circuit 2 has been correctly designed and meets its target design characteristics. A further form of testing may be debug testing of the data receiver circuit to ensure that it correctly receives stressed data of a form it is likely to encounter during normal operation.

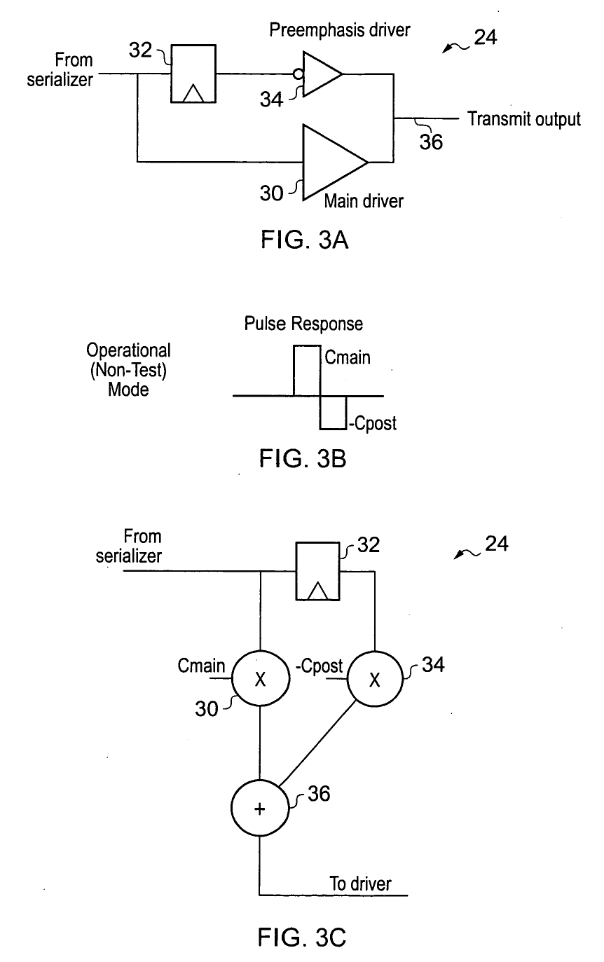

FIG. 2 schematically illustrates the data transmitter circuit 12 and the data receiver circuit 14. The data transmitter circuit 12 includes a serialiser 22 which receives the data to be transmitted from the serial data communication circuit 10 and generates a serial data signal therefrom. A filter circuit 24 functions to filter the output from the serialiser 22 so as to generate an output serial data signal. During an operational mode this output serial data signal will be output from the integrated circuit 2 to other circuits that are the destination for that serial data signal. During test mode operation a loopback connection 20, 20′ is illustrated which directs the output of the filter circuit 24 back to the data receiver circuit 14. The data receiver circuit 14 can include further filter circuitry 26 as well as a receiver unit 28 which identifies data values from the signal level detected for the received serial data signal.

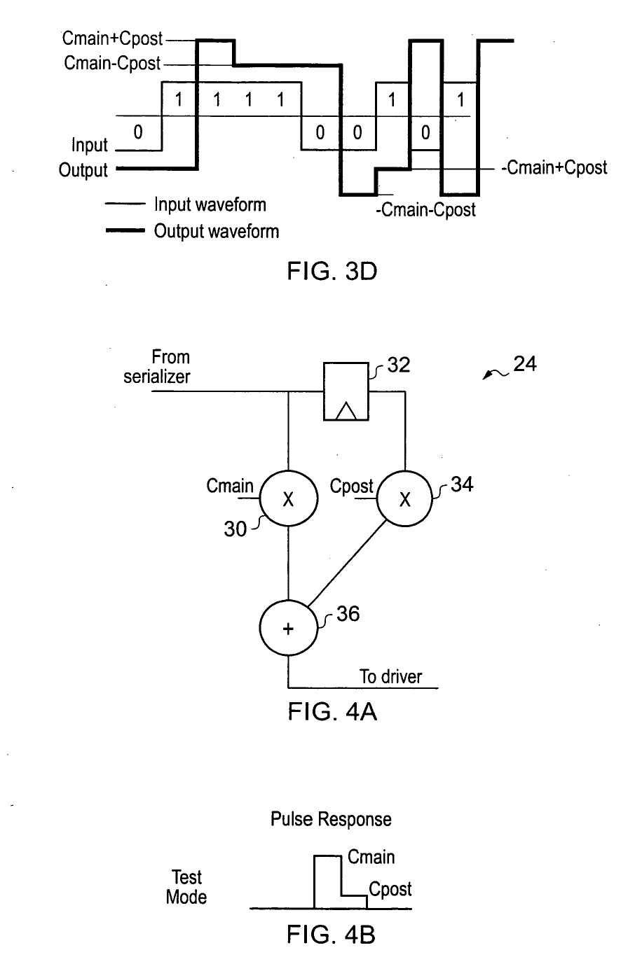

FIG. 3A illustrates the filter circuit 24 in more detail. This example filter circuit 24 is in the form of a two-stage finite impulse response filter. The main filter stage corresponds to the signal passed through a main driver 30. The following filter stage is provided by the action of a latch 32 and a pre-emphasis driver 34 (note the inverted input of the pre-emphasis driver 34 during the operational mode). The outputs from the pre-emphasis driver 34 and the main driver 30 are added to generate an output serial data signal 36.

FIG. 3B illustrates the pulse response of the two stage finite impulse response filter of FIG. 3A during the operational (non-test) mode. The inverted nature of the signal generated by the pre-emphasis driver 34 can be seen and this results in a destructive combination of the signals from the pre-emphasis driver 34 and the main driver 30. This destructive combination serves to reduce inter-symbol interference.

FIG. 3C illustrates an alternative view of the circuit of FIG. 3A. In this view the action of the joining of the output signal lines from the main driver 30 and the pre-emphasis driver 34 is represented by an adder 36. In an analog environment such an adder 36 may simply be the joining of two separately driven signal lines. The associated filter coefficients for the respective filter stages are shown as Cₘₐᵢₙ in respect of the main filter stage and —Cₚₒₛₜ in respect of the following filter stage.

FIG. 3D illustrates the relationship between an input signal waveform to the filter circuit 24 and the output waveform resulting therefrom. It will be seen that there is a one unit interval (UI) delay between the input and the output. The illustrated action of the filter in emphasising edges with the filter circuit 24 in the operational mode serves to reduce inter-symbol interference.

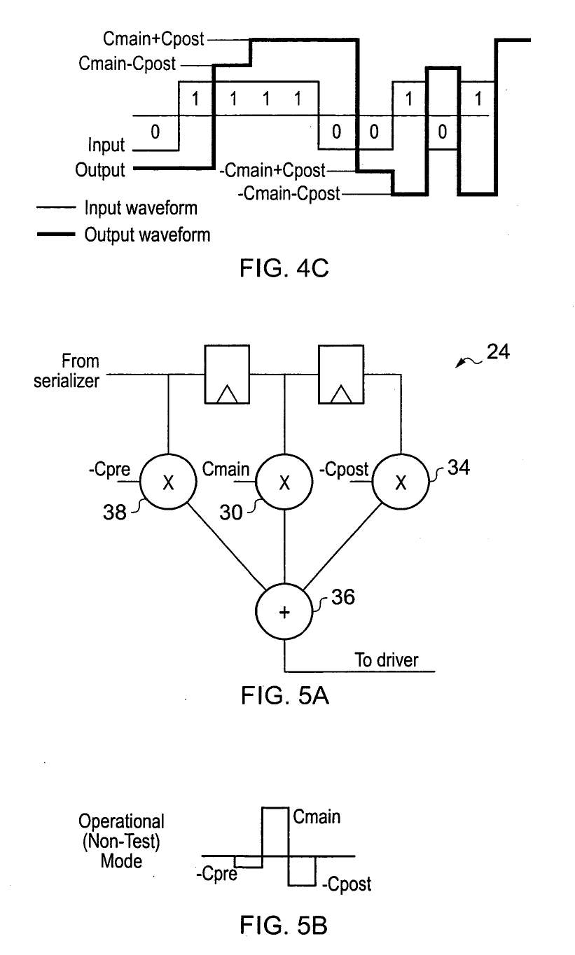

FIG. 4A is similar to FIG. 3C but in this case with the filter coefficient of the following filter stage (corresponding to the pre-emphasis driver 34) being changed in sign. This change of sign serves to configure the filter circuit 24 in a manner in which the output serial data signal therefrom constructively combines components from its different filter stages thereby serving to enhance inter-symbol interference. Such a serial data signal with enhanced inter-symbol interference would not normally be considered desirable to generate from the data transmitter circuit 12 provided within an integrated circuit 2. However, for the purposes of self-test such an output serial data signal with enhanced inter-symbol interference can usefully stress test the data receiver circuit 14 of the integrated circuit 2 in a convenient manner.

FIG. 4B illustrates the pulse response of the filter circuit 24 when operating in the test mode. The positive coeefficient Cₚₒₛₜ associated with the following filter stage in this test mode is illustrated.

FIG. 4C illustrates the relationship between the input waveform and the output waveform of the filter circuit 24 in test mode. The output waveform has enhanced inter-symbol interference in which the leading edges of transitions between signal values corresponding to different data values are reduced in magnitude in a manner which will stress test a data receiver circuit 12 aiming to correctly receive and interpret such a serial data signal.

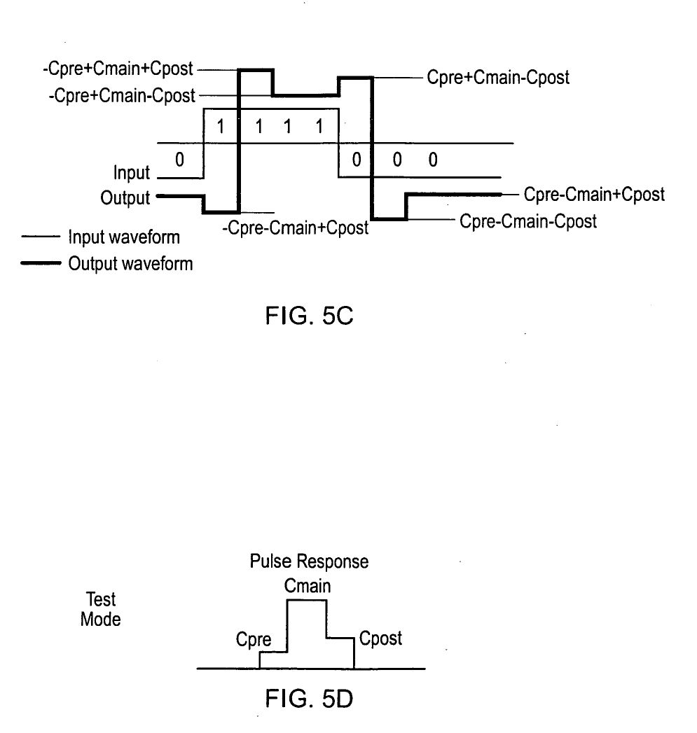

FIG. 5A illustrates a three-stage finite impulse response filter including both a pre-emphasis driver 34 and a post-emphasis driver 38. Such a three-stage finite impulse response filter can be used in an operational mode to reduce inter-symbol interference arising from both preceding data values and succeeding data values relative to a data value to be transmitted. The pulse response of the filter circuit 24 in the operational mode is illustrated in FIG. 5B. In the operational mode the outputs from the filter stages corresponding to the preceding and succeeding data values are destructively combined with the data value to be transmitted in a manner which reduces inter-symbol interference.

FIG. 5C schematically illustrates the relationship between the input waveform and the output waveform for the filter circuit 24 of FIG. 5A during the operational (non-test) mode.

FIG. 5D illustrates the pulse response for the filter circuit 24 of FIG. 5A when this is changed (reconfigured) to operate in the test mode in which the contribution from preceding and succeeding data values is constructively combined with a data value to be represented in a manner which enhances inter-symbol interference. The resulting output serial data signal can be used to test the data receiver circuit 14 of the integrated circuit 2 in a convenient self-test methodology.

Although illustrative embodiments of the invention have been described in detail herein with reference to the accompanying drawings, it is to be understood that the invention is not limited to those precise embodiments, and that various changes and modifications can be effected therein by one skilled in the art without departing from the scope and spirit of the invention as defined by the appended claims.

We claim:

1. An integrated circuit comprising:
a data receiver circuit; and
a test data generating circuit; wherein
said test data generating circuit includes a filter circuit responsive to an input test serial data signal to generate an output test serial data signal having enhanced inter-symbol interference for testing said data receiver circuit.

2. An integrated circuit as claimed in claim 1, wherein said filter circuit operates in a plurality of modes including:
a test mode to generate said output test serial data signal having enhanced inter-symbol interference; and
a non-test mode responsive to an input non-test serial data signal to generate an output non-test serial data signal having reduced inter-symbol interference.

3. An integrated circuit as claimed in claim 2, wherein said non-test mode is an operational mode and said test data generating circuit is a data transmitter circuit responsive to a serial data signal generated within said integrated circuit to generate a serial data signal for transmission off said integrated circuit with reduced inter-symbol interference.

4. An integrated circuit as claimed in claim 1, wherein a loopback connection carries said output test serial data signal from said test signal generating circuit to said data receiver circuit.

5. An integrated circuit as claimed in claim 4, wherein said loopback connection is one of:
an internal path within said integrated circuit; and
an external path between an output of said integrated circuit coupled to said test signal generating circuit and an input to said integrated circuit coupled to said data receiver circuit.

6. An integrated circuit as claimed in claim 1, wherein said filter circuit includes a finite impulse response filter having a plurality of filter stages.

7. An integrated circuit as claimed in claim 2, wherein said filter circuit includes a finite impulse response filter having a plurality of filter stages and at least one filter stage of said plurality of filter stages has an associated filter coefficient value that is changed when filter circuit changes between said test mode and said non-test mode.

8. An integrated circuit as claimed in claim 7, wherein said filter circuit includes a main filter stage and a following filter stage with respective associated filter coefficient values such that:
in said test mode outputs from said main filter stage and said following filter stage are constructively combined to enhance inter-symbol interference; and
in said non-test mode outputs from said main filter stage and said following filter stage are destructively combined to reduce inter-symbol interference.

9. An integrated circuit as claimed in claim 6, wherein said finite impulse response filter has three filter stages.

10. An integrated circuit as claimed in claim 1, wherein said output test serial data signal stress tests said data receiver circuit.

11. An integrated circuit as claimed in claim 1, wherein said output test serial data signal performs one or more of:
a manufacturing test upon said data receiver circuit to test that said data receiver circuit within an individual integrated circuit has been correctly manufactured;
a design characterisation test upon said data receiver circuit to test that said data receiver circuit within a given design of an integrated circuit has been correctly designed; and
a debug test test upon said data receiver circuit to test that said data receiver circuit within a given design of an integrated circuit functions to receive stressed data.

12. An integrated circuit as claimed in claim 1, wherein said data receiver circuit is formed to receive a stream of self-timed serial data.

13. An integrated circuit comprising:
data receiver means for receiving data; and
test data generating means for generating test data; wherein
said test data generating means includes filter means responsive to an input test serial data signal to generate an output test serial data signal having enhanced inter-symbol interference for testing said data receiver means.

14. A method of self-testing an integrated circuit having a data receiver circuit, said method comprising the steps of:
generating from an input test serial data signal using a filter circuit within said integrated circuit an output test serial data signal having enhanced inter-symbol interference; and
supplying said output test serial data signal to said data receiver circuit.
